(19) United States
(12) Patent Application Publication
(10) Pub. No.: US 2007/0266932 A1
(43) Pub. Date: Nov. 22, 2007

(54) VAPOR PHASE GROWTH APPARATUS AND METHOD FOR VAPOR PHASE GROWTH

(75) Inventor: Shoji Hiramatsu, Fukuoka-ken (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/750,589

(22) Filed: May 18, 2007

(30) Foreign Application Priority Data
May 18, 2006 (JP) 2006-139229

(51) Int. Cl. C30B 23/00; C30B 25/00; C23C 16/00

(52) U.S. Cl. 117/88; 117/92; 118/715

(57) ABSTRACT

In an aspect of the present invention, a vapor phase growth apparatus may include a chamber, a gas supply provided in the chamber, configured to supply a raw material gas from a central region outwardly, a susceptor provided above the gas supply in the chamber, being capable of revolve around the axis, and configured to mount a substrate facing downward, the substrate being inclined toward the axis, and a heater provided above the holder in the chamber.

### CROSS REFERENCE TO RELATED APPLICATION

This application is based upon and claims the benefit of priority from Japanese Patent Application No. 2006-139229, filed on May 18, 2006, the entire contents of which are incorporated herein by reference.

### BACKGROUND

In semiconductor light emitting elements or semiconductor laser elements, semiconductor layers are formed by a chemical vapor phase growth apparatus, such as an MOCVD (Metal Organic Chemical Vapor Deposition). The semiconductor layers are grown on a substrate.

A conventional vapor phase growth apparatus, in which a susceptor mounting a substrate with a growth surface of the substrate faces downward, is known.

This kind of vapor phase growth apparatus is a so-called face down type vapor phase growth apparatus.

### SUMMARY

Aspects of the invention relate to an improved vapor phase growth apparatus and an improved method for vapor phase growth.

In one aspect of the present invention, a vapor phase growth apparatus may include a chamber, a gas supply provided in the chamber, configured to supply a raw material gas from a central region outwardly, a susceptor provided above the gas supply in the chamber, being capable of revolve around the axis, and configured to mount a substrate facing downward, the substrate being inclined toward the axis, and a heater provided above the holder in the chamber.

In another aspect of the invention, In an aspect of the present invention, a method for vapor phase growth, comprising providing a substrate on a susceptor facing downward and being inclined toward an axis, revolving the susceptor about the axis, supplying a raw material gas from a central region outwardly below the susceptor, and heating the substrate.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross sectional view of a vapor phase growth apparatus in accordance with a first embodiment.

FIG. 2A is a plane view of a susceptor in accordance with a first embodiment. FIG. 2B is a cross sectional view of the susceptor taken along A-A line in FIG. 2A.

FIG. 3A is a plane view of a holder in accordance with a first embodiment. FIG. 3B is a cross sectional view of the holder taken along B-B line in FIG. 3A.

FIG. 4A is a plane view of an outer ring in accordance with a first embodiment. FIG. 4B is a cross sectional view of the outer ring taken along C-C line in FIG. 4A.

FIG. 5A is a plane view of the susceptor having the holder, the outer ring and a semiconductor substrate in accordance with a first embodiment. FIG. 5B is a cross sectional view of the susceptor having the holder, the outer ring and a semiconductor substrate taken along D-D line in FIG. 5A.

FIG. 6A is a cross sectional view showing the gas flow near the semiconductor substrate in accordance with a first embodiment. FIG. 6B is a cross sectional view showing the gas flow near the semiconductor substrate in accordance with a comparative example.

FIG. 7A is a plane view of a vapor phase grown substrate in accordance with a first embodiment. FIG. 7B is a vapor phase growth substrate in accordance with a comparative example.

FIG. 8 is a table of the number of exchanging holder and susceptor in accordance with the first embodiment and the comparative example.

FIG. 9 is a flow chart showing a manufacturing process of a vapor phase growth substrate in accordance with a first embodiment.

FIG. 10A is a cross sectional view of a vapor phase growth substrate in accordance with a first embodiment. FIG. 10B is a cross sectional view of a semiconductor optical device made from the vapor phase growth substrate as shown in FIG. 10A.

FIG. 11A is a distribution of a thickness of vapor phase growth substrate in accordance with a first embodiment. FIG. 11B is a distribution of a thickness of vapor phase growth substrate in accordance with a first comparative example. FIG. 11C is a distribution of a thickness of vapor phase growth substrate in accordance with a second comparative example.

FIG. 12 is a partial cross sectional view of a vapor phase growth apparatus in accordance with a second embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

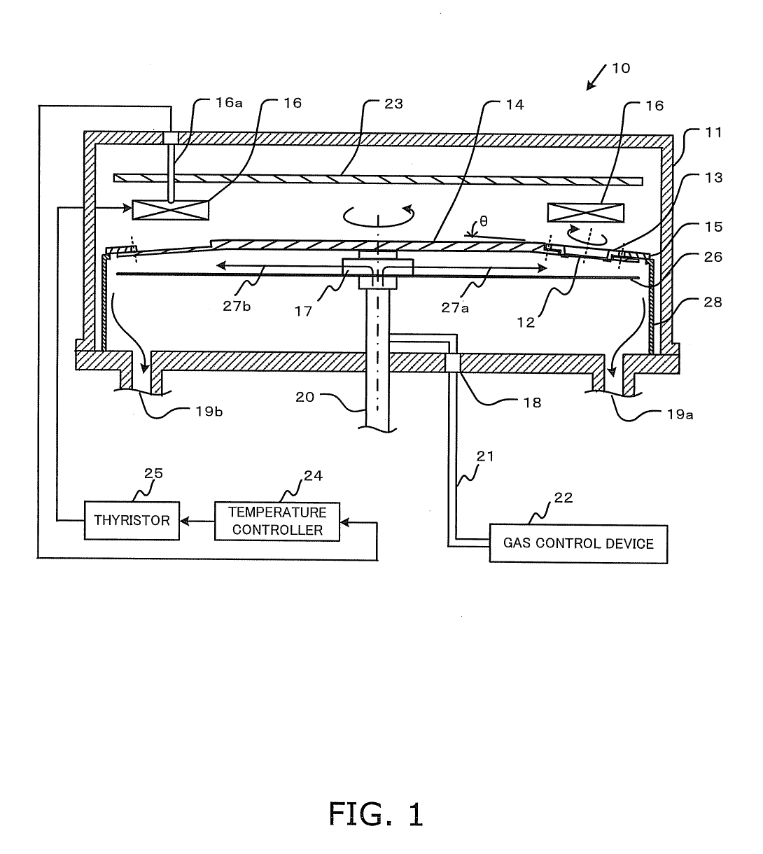

A first embodiment of the present invention will be explained hereinafter with reference to FIGS. 1-11.

First, a structure of a vapor phase growth apparatus 10 is explained hereinafter with reference to FIGS. 1-5B.

As shown FIG. 1, in the vapor phase growth apparatus 10, a holder 13, which holds a semiconductor substrate 12 and is capable of revolving and rotating around an axis, a susceptor 14, an outer ring 15, a heater 16, which is provided above the holder 14, and a nozzle 17, which is provided at a central region of the susceptor 14.

The semiconductor substrate 12 is configured to be mounted on the holder 13 so that the semiconductor substrate 12 faces downward.

A chamber 11 is an operating room for growing semiconductor layers on the semiconductor substrate 12. The chamber 11 may be made of stainless, for example, and have a water cooler jacket type structure. A gas inlet 18 is provided on a bottom surface of the chamber 11. Gas drains 19a and 19b are provided on the bottom surface of the chamber 11. A revolving axis 20, which is configured to revolve the susceptor 14 around thereof, is provided in the chamber 11. A sealing portion (not shown in FIG. 1), which is configured to seal the chamber 11 in an airtight manner, is provided in the chamber 11.

The gas inlet 18 is connected to a gas control device 22, which supplies a raw material gas to the chamber 11, via a gas tube 21.

The gas drains 19a and 19b are connected to an exhaust system (not shown in FIG. 1) via a gas exhaust tube (not shown in FIG. 1).

The heater 16 is a ring shaped carbon heater, which is coated by a SiC or the like, and provided above the semiconductor substrate 12 and holder 13. The heater 16 is configured to apply heat to the semiconductor substrate 12 from the bottom side (upper side in FIG. 1) of the semiconductor substrate 12.

A heat shield 23 is provided above the heater 16. The heat shield 16 is configured to prevent heat from the heater 16 from conveying to the top surface of the chamber 11 and to reflect a heat downwardly.

A thermocouple 16a is provided in a hole provided in the heater 16 via an insulator. The temperature of the semiconductor substrate 12 is monitored by the thermocouple 16a indirectly. The temperature monitored by the thermocouple 16a is inputted to a temperature controller 24. The temperature controller 24 is configured to control the power supply to the heater 16 by driving the thyristor such that the monitored temperature by the thermocouple 16a is as same as the target value. The temperature of the heater 16 is controlled by the power of the thyristor 25. So the temperature of the semiconductor substrate 12 is controlled suitably by controlling the temperature of the heater 16.

The gas from the nozzle 17 is supplied toward the outer region of the susceptor 13, passing between the susceptor 13 and the baffle plate 26. The raw material gases 27a and 27b may be flown as a laminar flow.

The revolving axis 20 is configured to turn the susceptor 14 around and revolve the semiconductor substrate 12 mounted thereon in respects to the revolving axis 20. The baffle plate 26 is attached on the revolving axis 20, and revolved around linking to the revolving axis 20. The revolving axis 20 may be a stainless shaft. In this embodiment, the source of the raw material gas is identical to the revolving axis. However, the source of the raw material gas may be supplied apart from the central region of the susceptor 14.

The outer ring 15 is coaxially provided with the susceptor 14 and outside of the susceptor 14. The outer ring 15 is provided on a supporting member 28, which has a cylindrical shape.

The holder 13 has a first trench, which has a gear shape, in a side surface of an outer portion 44. The outer ring 15 has a second trench, which has a gear shape and engages to the first trench of the holder 13, is a side surface of the outer ring 15.

When the susceptor 14 is revolved around the revolving axis 20, the holder 13 and the semiconductor substrate 12 mounted thereon is rotated.

In case the gear ratio of the holder 13 to the outer ring 15 is n, the holder 13 rotates n times with the susceptor 14 revolves one time.

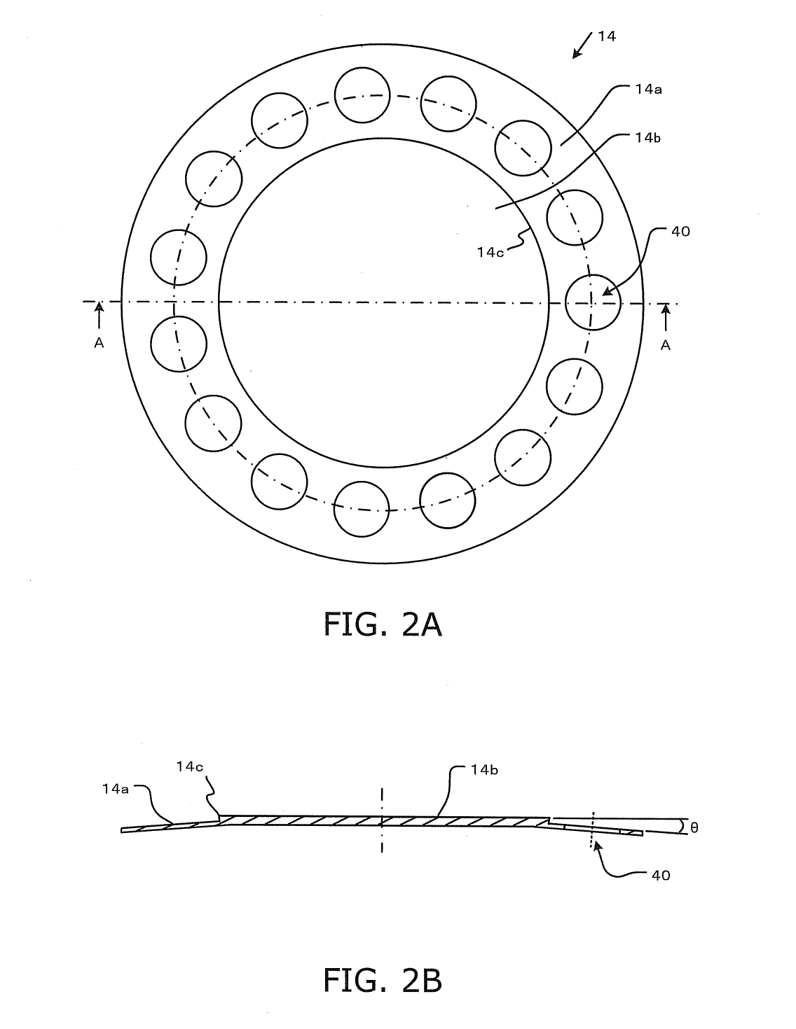

As shown in FIGS. 2A and 2B, the susceptor 14 has an umbrella shape, which the outer region 14a is slanted to the central region 14b. The outer region 14a of the susceptor 14 is slanted θ degrees against the central region 14b of the susceptor 14. In other words, the normal of the main surface of the outer region 14a is angled θ degrees against the normal of the main surface of the central region 14b of the susceptor 14. A step 14c is provided between the central region 14b and the outer region 14a. A plurality of openings 40, which is configured to mount a semiconductor substrate 13 thereon, is provided in the outer region 14a of the susceptor 14. The susceptor 14 may be made of a SiC coated carbon or the like.

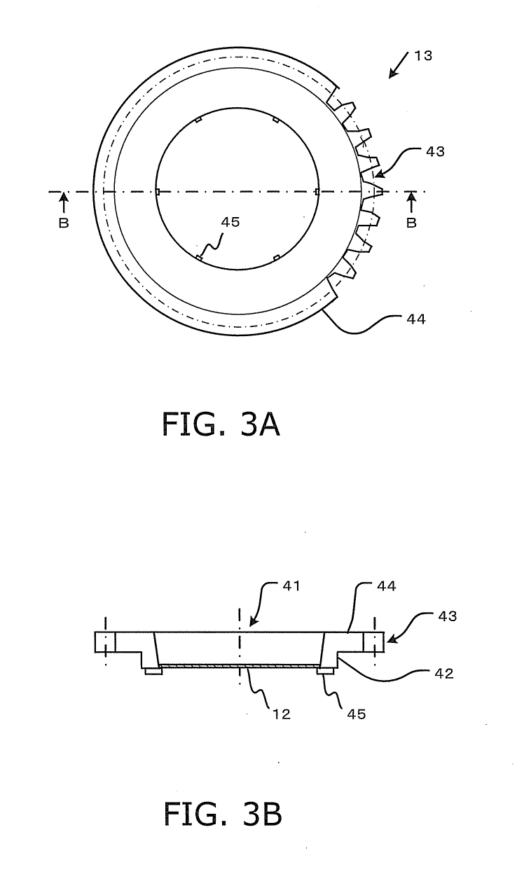

As shown in FIGS. 3A and 3B, the holder 13 has a body portion 42 and an outer portion 44. The body portion 42 has a second opening 41 which has a tapered inner surface and a protrusion 45 which is provided bottom of the holder 13 and toward inside of the second opening 41. The semiconductor substrate 12 is provided in the second opening 41 and supported by the protrusion 45. A first trench 43 is provided on the side surface of the outer portion 44. The holder 13 may be made of a SiC coated carbon.

The body portion 42 of the holder 13 is engaged to the first opening 40 of the susceptor 14. A surface of the semiconductor substrate 12 is mounted on the holder 13 such that the surface of the semiconductor substrate 12 is angled θ degrees against the normal of the main surface of the central region 14b of the susceptor 14. Namely, the semiconductor substrate 12 is angled θ degrees against the revolving axis 20.

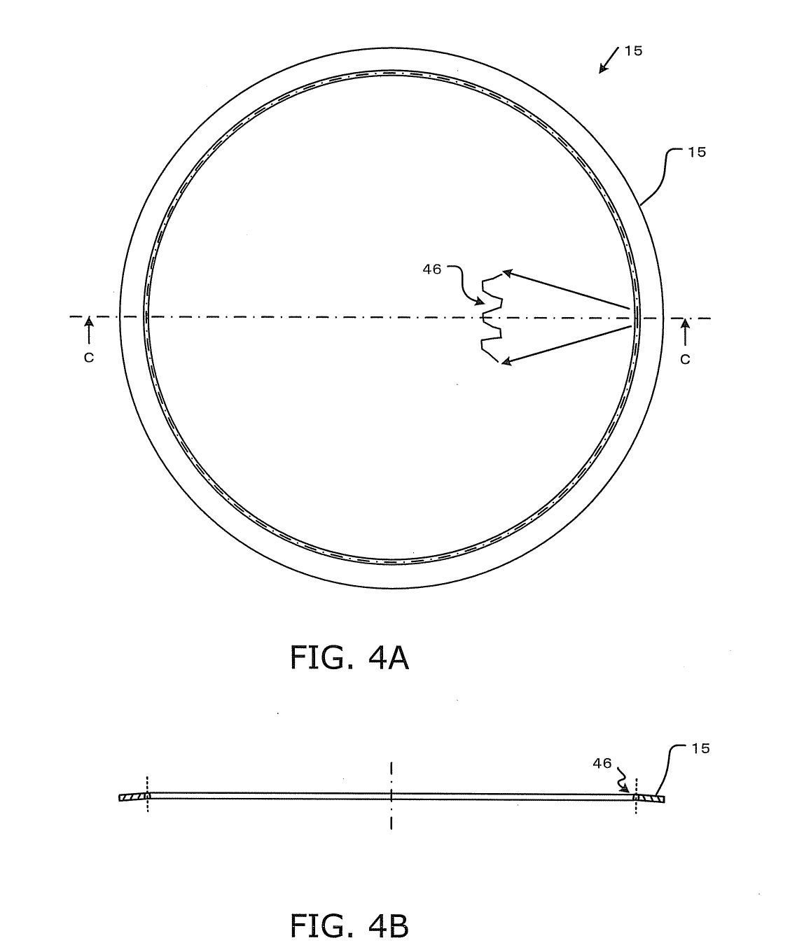

As shown in FIG. 4, the outer ring 15 has a second trench 46 in its inner surface. The second trench 46 is configured to engage to the first trench 43 of the holder 13.

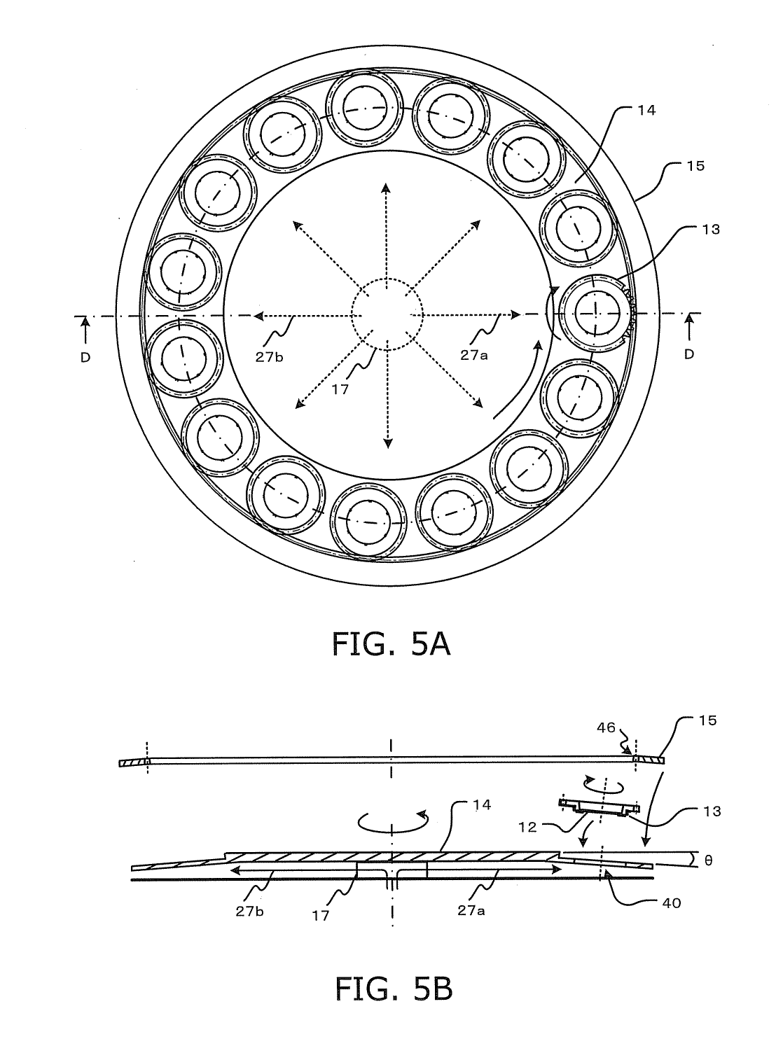

As shown in FIG. 5, the surface of the semiconductor substrate 12 is inclined to the direction of the gas flow 27a and 27b. In other words, the surface of the semiconductor substrate 12 is not parallel to the direction of the gas flow 27a and 27b. The semiconductor substrate 12 faces down ward, the revolving axis 20, and the source of the raw material gas. The nozzle 17, which is a source of the raw material gas, is provided below the center of the susceptor 14. The gas is supplied from the center of the susceptor 14. However, the gas may be supplied or flown from a portion below the central region 14b of the susceptor 14.

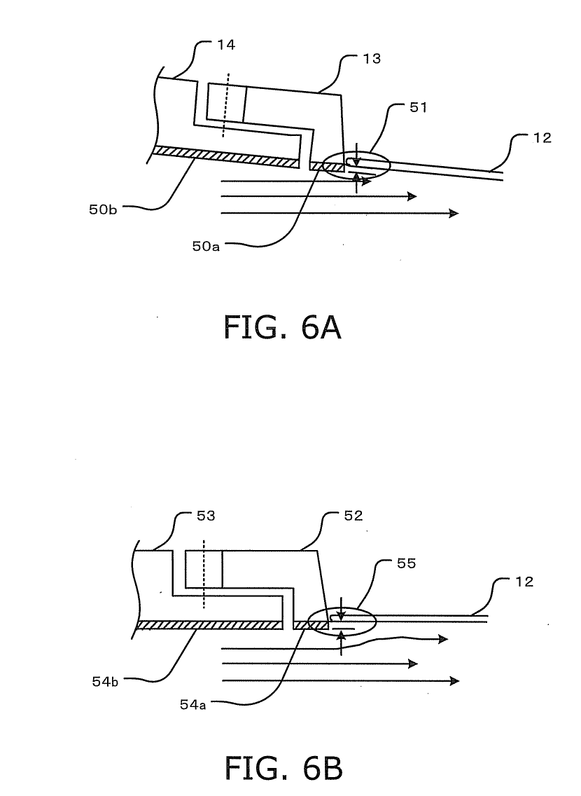

FIG. 6A is a cross sectional view showing a gas flow near the semiconductor substrate 12 in accordance with a first embodiment. FIG. 6B is a cross sectional view showing a gas flow near the semiconductor substrate 12 in accordance with a comparative example.

At first, the gas flow near the semiconductor substrate 12 in accordance with the comparative example will be explained with reference to FIG. 6B. In the comparative example, the semiconductor substrate 12, which is mounted on a holder 52, is parallel to the flow direction of the raw material gas. The holder 52 is held by a susceptor 53. Sediments 54a and 54b from the raw material gas are created on the holder 52 and susceptor 53. So a step 55 is formed between the holder 52 and the semiconductor substrate 12. After repetition of the crystal growth, the amount of the sediments 54a and 54b is increased, and the step 55 is increased.

As increasing the amount of the sediments 54a, the flow of the raw material gas may be disturbed by the step 55. So the raw material gas hardly reaches to the outer portion of the semiconductor substrate 12. In other words, the raw material gas is hardly provided onto the substrate 12 adjacent to the holder 52 or shaded by the step 55. A part of the shaded portion is circled in FIG. 6B.

Thus, crystal defects such as so called hatch are generated at the outer portion of the semiconductor substrate 12, since the raw material gases are deformed.

On the other hand, as shown in FIG. 6A, sediments 50a are formed on the holder 13 and sediments 50b are formed on the susceptor 14 by crystal growth. A step 51 is provided between the surface of the semiconductor substrate 12 and the bottom surface of the sediments 50a.

However, the raw material gas flow is hardly distorted, since the semiconductor substrate 12 is slanted and faced toward the source of the raw material gas. So the raw material gas reaches more easily to the outer portion of the semiconductor substrate 12 than the conventional way. A shaded portion from the sediments is decreased.

Thus, the deformation of the flow of raw material gas at the outer portion of the semiconductor substrate 12 is decreased, and the crystal defects, such as so called hatch, at the outer portion of the semiconductor substrate 12 are decreased.

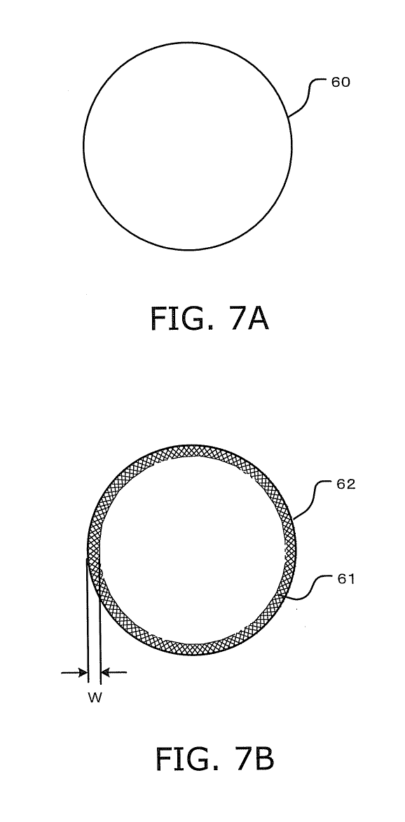

FIG. 7A is a plane view of a vapor phase grown substrate 60 in accordance with a first embodiment. FIG. 7B is a vapor phase growth substrate 61 in accordance with a comparative example.

As shown in FIG. 7A, a vapor phase growth substrate 60, which has low crystal defects at the outer portion of the substrate, is obtained in accordance with the present embodiment.

On the other hand, a vapor phase growth substrate 62, which has crystal defects 61 at the outer portion of the substrate, is obtained in accordance with the comparative example.

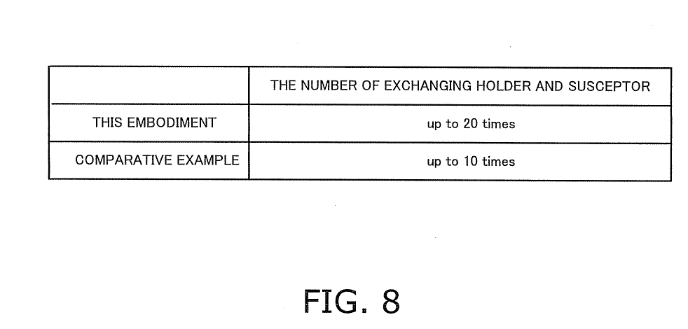

FIG. 8 is a table of the number of exchanging holder and susceptor in accordance with the first embodiment and the comparative example.

As shown in FIG. 8, in case the step 55 is equal to or more than about 300 μm, crystal defects having 3 mm in width is generated at the outer portion of the substrate.

The thickness of the sediments 54a and 54b is about 3 μm at a single crystal growth. So when the crystal growth is operated for 10 times, the step 55 may be 300 μm in thickness. So exchanging the holder 52 and the susceptor 53 is necessary after 10 times crystal growth in the comparative example.

On the other hand, in this embodiment, the crystal defects are not provided when the semiconductor substrate 12 is angled about 10 degrees until the step 51 is about 600 μm. So exchanging the holder 13 and the susceptor 14 may be operated after 20 times when the step 51 may be equal to or more than 600 μm in accordance with this embodiment.

So, the frequency of exchanging the holder 13 and the susceptor 14 in this embodiment may be decreased with comparing to the comparative example.

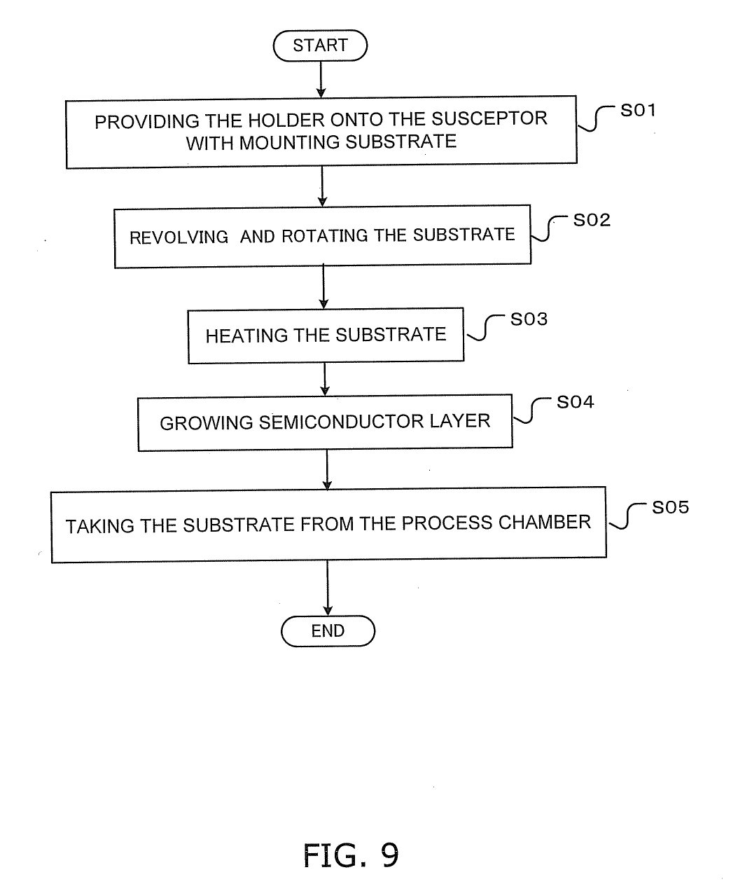

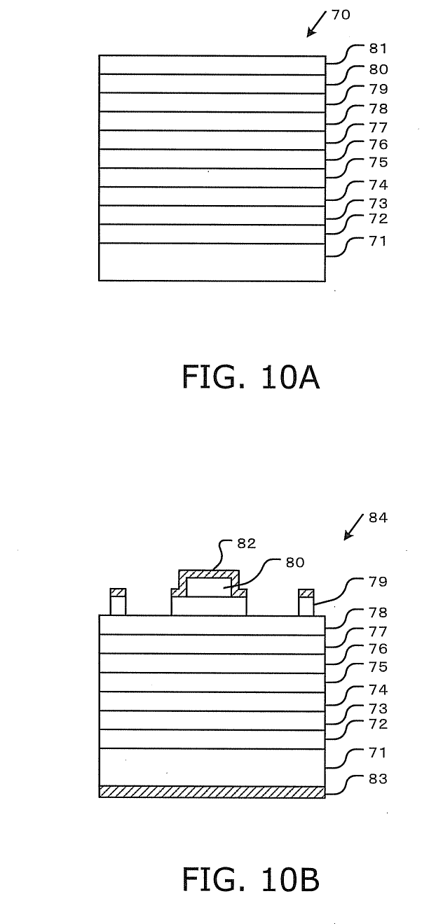

A manufacturing process of a light emitting element having a InGaAlP based semiconductor light emitting layer on GaAs substrate, using above mentioned vapor phase growth apparatus, is explained hereinafter with reference to FIGS. 9-10B.

FIG. 9 is a flow chart showing a manufacturing process of a vapor phase growth substrate in accordance with a first embodiment. FIG. 10A is a cross sectional view of a vapor phase growth substrate in accordance with a first embodiment. FIG. 10B is a cross sectional view of a semiconductor optical device made from the vapor phase growth substrate as shown in FIG. 10A.

Step S01.

As shown in FIG. 9, the holder 13 mounting semiconductor substrate 12 is mounted on the susceptor 14, which is angled about 10 degrees to the raw material gas flow direction.

Step S02.

The susceptor 14 starts to revolve. The semiconductor substrate 12 is revolved 10 rpm and rotated 50 rpm.

Step S03.

A hydrogen gas as a carrier gas and an arsine (AsH3) gas as a volatile control gas for As from GaAs substrate is flown, and the semiconductor substrate 12 is heated to the growth temperature of the semiconductor layer.

Step S04.

TMG (Trimethylgallium), TMA (Trimethylaluminium), TMI (Trimethylindium), arsine, PH3 (Phosphine), DMZ (dimethylzinc) as P type dopant, SiH4 (Silane) as N type dopant are flown onto the GaAs substrate, and semiconductor layers are formed on the GaAs substrate.

As shown in FIG. 10A, an N type GaAs buffer layer 72, a reflection layer 73, which an N type InAlP layer and an N type InGaAlP layer are alternatively laminated, an N type InAlP cladding layer 74, an active layer (MQW: Multi Quantum Well) 75, which an InGaP layer and an InGaAlP layer are alternatively laminated, a P type InAlP cladding layer 76, a P type GaAlAs current diffusion layer 77, a P type InGaAlP moisture blocking layer 78, a P type GaAs contact layer 79, an N type InGaAlP current blocking layer 80, and InGaAlP cap layer 81 are formed on the N type GaAs substrate 71 in this order. So a vapor phase growth substrate 70 is obtained.

Step S05.

The vapor phase growth substrate 70 is cooled down, and taken out from the chamber 11.

When the number of the vapor phase growths is less than a predetermined value, for example 20 times, the vapor phase growth is operated with the same holder 13 and the same susceptor 14.

On the other hand, when the number of the vapor phase growths is equal to or more than the predetermined value, the holder 13 and the susceptor 14 are exchanged to other holder 13 and susceptor 14, on which sediments are not provided.

As shown in FIG. 10B, a P side electrode 82 and an N side electrode 83 are provided on the vapor growth substrate 70, and a light emitting element 84 is obtained.

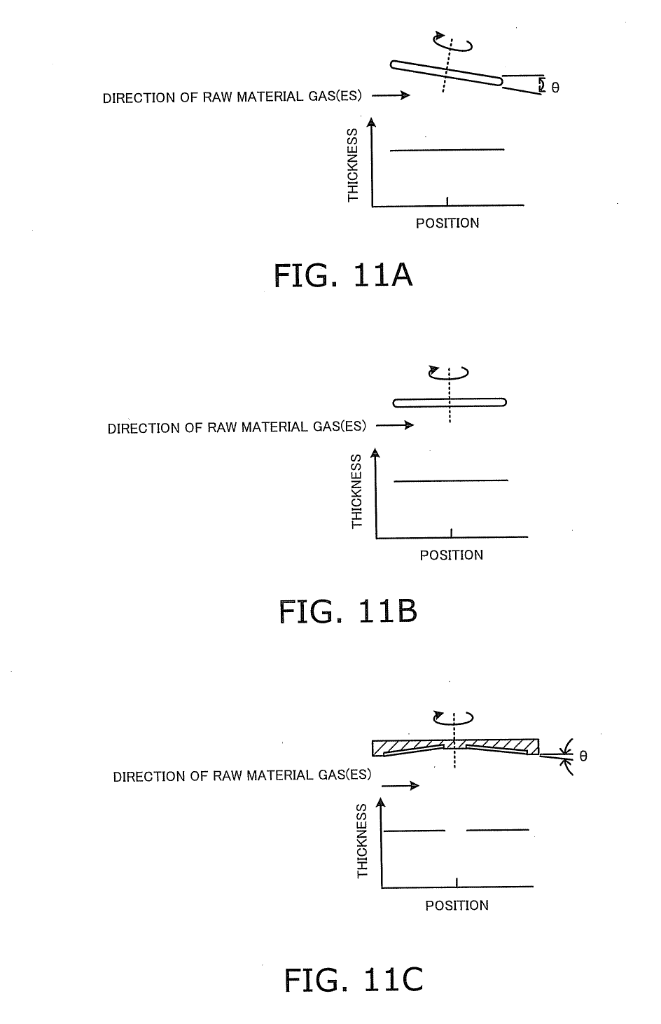

FIG. 11A is a distribution of a thickness of vapor phase growth substrate 70 in accordance with a first embodiment. FIG. 11B is a distribution of a thickness of vapor phase growth substrate in accordance with a first comparative example. FIG. 11C is a distribution of a thickness of vapor phase growth substrate in accordance with a second comparative example.

As shown in FIG. 11A, in this embodiment, the semiconductor substrate is angled θ degrees from the direction of the raw material gas flow direction. So substantially uniform thickness semiconductor layer is obtained. The growth substrate of this embodiment may have low crystal defect at outer portion of the substrate.

In this embodiment, the angle θ is about 10 degree. However the angle is not limited thereto. The angle may be from about 5 to about 15 degrees. Furthermore, the angle θ may be less than about 5 degrees or more than about 15 degrees in accordance with the amount of the gas flow, the flow rate of the raw material gas or the like.

### Second Embodiment

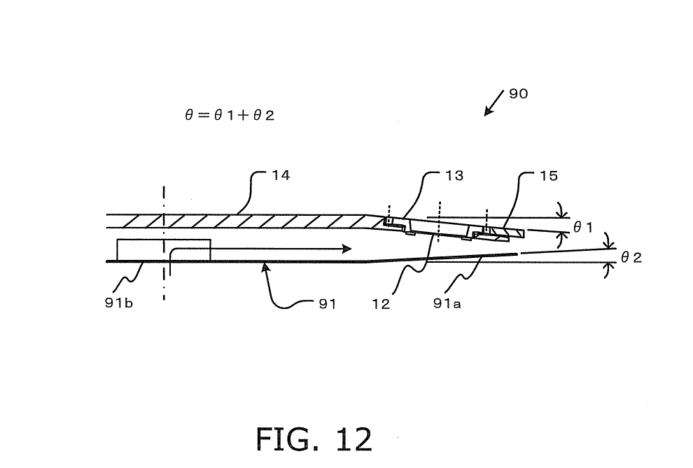

A second embodiment is explained with reference to FIGS. 12A-13B.

A semiconductor light emitting device 81 is described in accordance with a second embodiment of the present invention. With respect to each portion of this embodiment, the same or corresponding portions of the semiconductor light emitting device of the first embodiment shown in FIGS. 1-11 are designated by the same reference numerals, and explanation of such portions is omitted.

In this second embodiment, a guide board 91 is provided below the holder 13. The guide board is angled θ2 from the direction of the raw material gas flow, and faces toward the source of the raw material gas. The outer portion 91a of the guide board 91 (right side in FIG. 12) is positioned upper than the inner portion 91b of the guide board 91. In other words, the outer portion 91a of the guide board 91 is angled θ2 degrees from the horizontal line.

The raw material gas from the flow width is narrowed below the holder 13 or semiconductor substrate 12. So an effective angle θ degrees from the direction of the raw material gas to the surface of the mounting surface of the holder 13 is substantially enlarged. Namely, the effective angle θ degrees may be equal to the angle added θ1 and θ2 degrees.

Thus the distortion of the raw material gas in the outer portion of the semiconductor substrate 12 may be reduced or eliminated. So the growth substrate with low crystal defects may be obtained.

The angle θ1 may be equal to or more than the angle θ2. The angle may be less than the angle θ2.

Embodiments of the invention have been described with reference to the examples. However, the invention is not limited thereto.

In the embodiments, the substrate mounted on the holder is explained with the semiconductor substrate. However, the substrate is not limited to semiconductor. An insulating substrate, a metal substrate or the like may be applicable to the embodiments.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A vapor phase growth apparatus, comprising:
a chamber;
a gas supply provided in the chamber, configured to supply a raw material gas from a central region outwardly;
a susceptor provided above the gas supply in the chamber, capable of revolving around the axis, and configured to mount a substrate facing downward, the substrate being inclined toward the axis; and
a heater provided above the holder in the chamber.

2. A vapor phase growth apparatus of claim 1, wherein the substrate is capable of rotating.

3. A vapor phase growth apparatus of claim 1, wherein the raw material gas is flown to a direction parallel to the surface of the susceptor below the central region.

4. A vapor phase growth apparatus of claim 1, wherein the raw material gas is supplied from the axis of the susceptor.

5. A vapor phase growth apparatus of claim 1, wherein the susceptor is configured to mount a substrate in an outside of the central region.

6. A vapor phase growth apparatus of claim 1, wherein the substrate is inclined at an angle from about 5 to about 15 degrees.

7. A vapor phase growth apparatus of claim 1, further comprising a guide board provided below the susceptor and a flow of the raw material gas.

8. A vapor phase growth apparatus of claim 7, wherein the guide board is parallel to the susceptor in the central region and the guide board is inclined to the axis and the susceptor outside of the central region.

9. A vapor phase growth apparatus of claim 2, further comprising a guide board provided below the susceptor and the raw material gas.

10. A vapor phase growth apparatus of claim 9, wherein the guide board is parallel to the susceptor in the central region and the guide board is inclined to the axis and the susceptor outside of the central region.

11. A method for vapor phase growth, comprising:
providing a substrate on a susceptor facing downward and being inclined toward an axis;
revolving the susceptor about the axis;
supplying a raw material gas from a central region outwardly below the susceptor; and
heating the substrate.

12. A method for vapor phase growth of claim 11, further comprising rotating the substrate.

13. A method for vapor phase growth of claim 11, wherein the raw material gas is flown to a direction parallel to the surface of the susceptor below the central region.

14. A method for vapor phase growth of claim 11, wherein the raw material gas is supplied from the axis of the susceptor.

15. A method for vapor phase growth of claim 11, wherein the susceptor is configured to mount a substrate in an outside of the central region.

16. A method for vapor phase growth of claim 11, wherein the substrate is inclined at an angle from about 5 to about 15 degrees.

17. A method for vapor phase growth of claim 11, further comprising a guide board provided below the susceptor and a flow of the raw material gas.

18. A method for vapor phase growth of claim 17, wherein the guide board is parallel to the susceptor in the central region and the guide board is inclined to the axis and the susceptor outside of the central region.

19. A method for vapor phase growth of claim 12, further comprising a guide board provided below the susceptor and the raw material gas.

20. A method for vapor phase growth of claim 19, wherein the guide board is parallel to the susceptor in the central region and the guide board is inclined to the axis and the susceptor outside of the central region.
